(19) United States
(12) Patent Application Publication
(10) Pub. No.: US 2021/0397101 A1
(43) Pub. Date: Dec. 23, 2021

(54) OVERLAY COMPENSATION METHOD, EXPOSURE SYSTEM, SERVER AND READABLE STORAGE MEDIUM

(71) Applicant: CHANGXIN MEMORY TECHNOLOGIES, INC., Hefei City (CN)

(72) Inventor: Peng DONG, Hefei (CN)

(73) Assignee: CHANGXIN MEMORY TECHNOLOGIES, INC., Hefei City (CN)

(21) Appl. No.: 17/446,825

(22) Filed: Sep. 2, 2021

Related U.S. Application Data
(63) Continuation of application No. PCT/CN2021/079374, filed on Mar. 5, 2021.

(30) Foreign Application Priority Data
Mar. 10, 2020 (CN) 202010162595.6

(51) Int. Cl. G03F 7/20

(52) U.S. Cl. CPC G03F 7/70633; G03F 7/70433

(57) ABSTRACT

An overlay compensation method can be applied to a wafer, and include: acquiring overlays of an exposed wafer; dividing the exposed wafer into a plurality of regions; calculating compensation values corresponding to the regions respectively according to the overlays corresponding to the regions; and compensating corresponding regions of a to-be-exposed wafer respectively by using the compensation values. The overlay compensation method, the exposure system, the server and the computer-readable storage medium can improve the accuracy of overlay compensation for a wafer and improve a product yield.

### CROSS-REFERENCE TO RELATED APPLICATIONS

This application is a continuation of International Patent Application No. PCT/CN2021/079374 filed on Mar. 5, 2021, which claims priority to Chinese Patent Application No. 202010162595.6 filed on Mar. 10, 2020. The above-referenced applications are hereby incorporated by reference in their entirety.

### BACKGROUND

In a lithography process, a pattern after exposure and development (a current layer) of a wafer has to be aligned with an existing pattern (a previous layer) on a wafer substrate to ensure a correct connection between devices. A relative position between the current layer and the previous layer of the exposed pattern is called an overlay. A too large overlay may cause a short circuit or an open circuit to the devices, thereby affecting a product yield.

### SUMMARY

Embodiments of the present application relate generally to the field of semiconductor technologies, and more specifically to an overlay compensation method, a wafer exposure system, a server and a computer-readable storage medium.

An objective of the embodiments of the present application is to provide an overlay compensation method, a wafer exposure system, a server and a computer-readable storage medium, which can reduce overlays of a wafer and improve a product yield.

The embodiments of the present application provide an overlay compensation method applied to a wafer, including: acquiring overlays of an exposed wafer; dividing the exposed wafer into a plurality of regions; calculating compensation values corresponding to the regions respectively according to the overlays corresponding to the regions; and compensating corresponding regions of a to-be-exposed wafer respectively by using the compensation values.

The embodiments of the present application further provide a wafer exposure system, including: a control apparatus, and an acquisition apparatus and a lithography machine that are connected to the control apparatus; the acquisition apparatus being configured to acquire overlays of an exposed wafer; the control apparatus being configured to divide the exposed wafer into a plurality of regions, and calculate compensation values corresponding to the regions respectively according to the overlays corresponding to the regions; and the lithography machine being configured to compensate corresponding regions of a to-be-exposed wafer respectively by using the compensation values.

The embodiments of the present application further provide a server, including: at least one processor; and a memory in communication connection with the at least one processor; wherein the memory stores instructions executable by the at least one processor, the instructions being executed by the at least one processor to enable the at least one processor to perform the overlay compensation method described as above.

The embodiments of the present application further provide a computer-readable storage medium storing a computer program, wherein the computer program, when executed by the processor, implements the overlay compensation method described above.

According to the embodiments of the present application, overlays of an exposed wafer are acquired, the exposed wafer is divided into a plurality of regions, compensation values corresponding to the regions are calculated respectively according to the overlays corresponding to the regions, and corresponding regions of a to-be-exposed wafer are compensated respectively by using the compensation values; that is, compensation values of different regions of the exposed wafer are obtained by using overlays of the different regions, and the regions of the to-be-exposed wafer are compensated respectively by using the compensation values of the regions, which not only realizes the compensation for the different regions of the wafer, but also can perform continuous update and compensation according to an actual situation, so as to improve the accuracy of the compensation for the wafer, reduce overlays of the wafer and improve a product yield.

Further, process conditions for forming the exposed wafer and the to-be-exposed wafer are identical. In this way, the compensation values of the regions calculated according to the overlays of the exposed wafer can be better applied to the compensation for the regions of the to-be-exposed wafer.

Further, prior to the step of compensating corresponding regions of a to-be-exposed wafer respectively by using the compensation values, the overlay compensation method further includes: judging whether physical properties and/or process conditions of the regions of the to-be-exposed wafer match the overlays; and performing, if yes, the step of compensating corresponding regions of a to-be-exposed wafer respectively by using the compensation values. In this way, a problem of inaccurate compensation for the corresponding regions of the to-be-exposed wafer caused by a data error in the overlays can be avoided, thereby improving the accuracy of the compensation for the wafer.

Further, the step of dividing the exposed wafer into a plurality of regions specifically includes: dividing the exposed wafer into a central region and an edge region surrounding the central region or dividing the exposed wafer into two semicircular regions. Since positions at different distances from a center of the wafer or two semicircular regions may result in different overlays, the exposed wafer is divided into a central region and an edge region arranged around the central region or two semicircular regions, so that the regions of the to-be-exposed wafer can be compensated more accurately and the overlays of the wafer can be reduced.

Further, the step of dividing the exposed wafer into a plurality of regions specifically includes: dividing the exposed wafer into the plurality of regions according to the overlays of the exposed wafer. In this way, several regions with large overlay differences can be classified into different regions and compensation values are calculated respectively, so as to improve a coincidence degree of compensation value and overlay curves.

Further, the step of dividing the exposed wafer into the plurality of regions according to the overlays of the exposed wafer specifically includes: setting an overlay threshold, classifying positions of the overlays greater than or equal to the overlay threshold into one region, and classifying positions of the overlays less than the overlay threshold into another region.

Further, the step of dividing the exposed wafer into the plurality of regions according to the overlays of the exposed wafer specifically includes: setting N(N>=2) overlay thresholds, and dividing the exposed wafer into N+1 regions according to a threshold interval composed of the overlay thresholds.

Further, the compensation value is a first-order compensation value, and the first-order compensation value is updated online.

Further, the compensation value includes: any one of a rotation compensation value, an expansion compensation value and a translation compensation value and any combination thereof.

### BRIEF DESCRIPTION OF THE DRAWINGS

FIG. 1 is a flowchart of an overlay compensation method according to an embodiment of the present application;

FIG. 2 is a schematic diagram of division of an exposed wafer into a central region and an edge region according to an embodiment of the present application;

FIG. 3 is a simulation diagram of compensation values and overlays according to an embodiment of the present application;

FIG. 4 is a schematic structural diagram of a wafer exposure system according to an embodiment of the present application; and

FIG. 5 is a schematic structural diagram of a server according to an embodiment of the present application.

### DETAILED DESCRIPTION

In order to make the objectives, technical solutions and advantages of the present application clearer, the embodiments of the present application are clearly and fully described below with reference to the accompanying drawings in the embodiments of the present application. It is apparent that the embodiments described are merely some rather than all of the embodiments of the present application. Other embodiments obtained by those of ordinary skill in the art based on the embodiments of the present application without creative efforts all fall within the protection scope of the present application.

A typical overlay compensation method is to calculate measurement points on a surface of the wafer comprehensively to obtain an optimum value, so as to perform average compensation for the entire wafer.

The inventor of the present disclosure has recognized that typical methods can have at least the following problems: since different positions may produce overlays having large differences, with a method of performing average compensation for the entire wafer by using a same compensation value, overlay residue of the whole wafer is still large after compensation, and the product yield is still in need of improvement. Although the wafer can be compensated non-uniformly by using Gridmapper subrecipe, the establishment of the

Gridmapper subrecipe requires collection of a large number of data points and also requires manual updates. The wafer cannot be compensated effectively by the Gridmapper subrecipe once a wafer manufacturing process changes significantly.

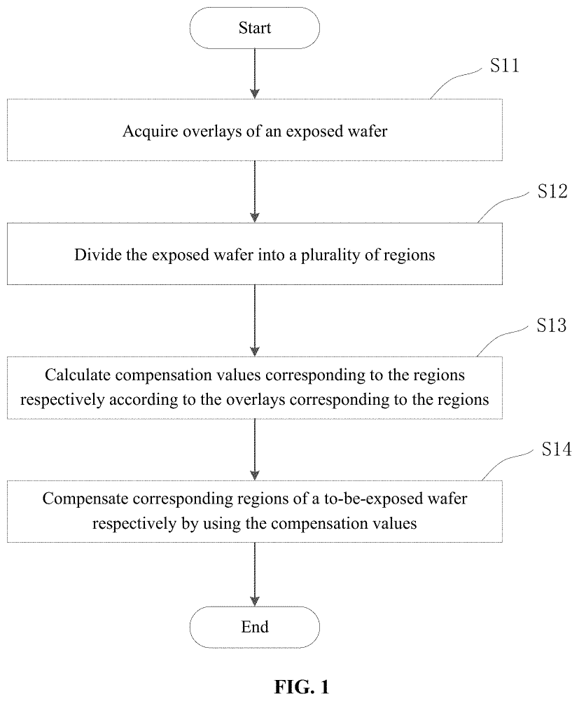

With respect to the above problems, an embodiment of the present application relates to an overlay compensation method. A core of this embodiment lies in that, as shown in FIG. 1, the overlay compensation method includes the following steps: S11: acquiring overlays of an exposed wafer; S12: dividing the exposed wafer into a plurality of regions; S13: calculating compensation values corresponding to the regions respectively according to the overlays corresponding to the regions; and S14: compensating corresponding regions of a to-be-exposed wafer respectively by using the compensation values. Overlays of an exposed wafer are acquired, the exposed wafer is divided into a plurality of regions, compensation values corresponding to the regions are calculated respectively according to the overlays corresponding to the regions, and corresponding regions of a to-be-exposed wafer are compensated respectively by using the compensation values; that is, compensation values of different regions of the exposed wafer are obtained by using overlays of the different regions, and the regions of the to-be-exposed wafer are compensated respectively by using the compensation values of the regions, which not only realizes the compensation for the different regions of the wafer, but also can perform continuous update and compensation according to an actual situation, so as to improve the accuracy of the compensation for the wafer, reduce overlays of the wafer and improve a product yield.

Implementation details of the overlay compensation method according to this embodiment are specifically described below. The following contents are only implementation details provided for ease of understanding, and are not necessary for the implementation of this solution.

The overlay compensation method according to this embodiment specifically includes the following steps.

In S11, overlays of an exposed wafer are acquired.

In this step, the overlays of the exposed wafer are acquired. Specifically, the exposed wafer may be selected from one or more to-be-exposed wafers, and the exposed wafer may also be one or more wafers in a same product that are produced in previous batches. Overlays on each wafer can be measured from overlay marks at each position or some positions on all shots in each wafer, or from overlay marks at each position or some positions on some shots in each wafer. It should be noted that process conditions for the exposed wafer and the to-be-exposed wafer are identical. Specifically, the exposed wafer and the to-be-exposed wafer are identical in product model, shipment process, shipment process parameter, and so on. In this way, the compensation values of the regions calculated according to the overlays of the exposed wafer can be better applied to the compensation for the corresponding regions of the to-be-exposed wafer. That is, on a pipeline of wafer exposure processing, compensation values of overlays of next wafer can be calculated by using overlays of a previous wafer after exposure.

It may be understood that overlays of first N exposed wafers of the to-be-exposed wafer may also be acquired, and an average value of the overlays of the first N exposed wafers is calculated as an overlay of the exposed wafer. That is, an average value of the overlays of first positions of the first N exposed wafers is used as an overlay of a first position of the wafer, an average value of the overlays of second positions of the first N exposed wafers is used as an overlay of a second position of the wafer, and so on. In this way, a contingency of overlays of an exposed wafer can be avoided, thereby improving the accuracy of measurement values of the overlays of the wafer.

In S12, the exposed wafer is divided into a plurality of regions.

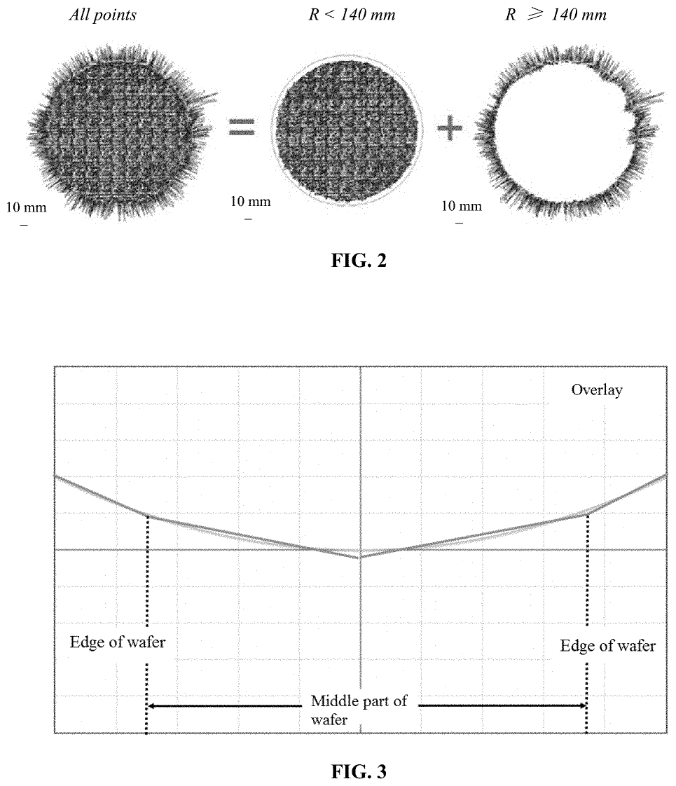

Since process conditions for forming a wafer are often not ideal or physical properties of the wafer formed are quite different, overlays of different regions on the wafer may be quite different. All regions cannot be compensated optimally if the to-be-exposed wafer is compensated by using a same compensation value, so the exposed wafer is required to be divided into regions. For example, since etched ions at positions at different distances from a center of the wafer vary in density and direction, overlay marks of a previous layer formed by etching are at different positions in shots at different distances from the center of the wafer, thereby resulting in a significant difference between overlay marks of a current layer and the overlay marks of the previous layer. As shown in FIG. 2 which is a schematic diagram of division of an exposed wafer into a central region and an edge region, the central region is a concentric circle of the exposed wafer, and the concentric circle has a diameter of 140 mm. In other cases, for example, distortion of the overlay marks of the previous layer at different positions on the wafer caused by chemical mechanical polishing (CMP) may also result in significant differences in the overlays at different positions from the center of the wafer. Therefore, the exposed wafer is divided into a central region and an edge region arranged around the central region, so that the regions of the to-be-exposed wafer can be compensated more accurately and the overlays of the wafer can be reduced.

In another example, the exposed wafer may also be divided into two semicircular regions. An exposure table of the lithography machine may lead to differences between heights of left and right semicircles of the wafer adsorbed thereon, which may affect the overlays of the exposed wafer. The accuracy of the compensation can be improved by dividing the exposed wafer into two semicircular regions and performing overlay compensation for the two semicircular regions respectively.

It may also be understood that the exposed wafer may also be divided into the plurality of regions according to the overlays of the exposed wafer. That is, the overlays within a first error range are taken as a first region, the overlays within a second error range are taken as a second region, and so on. The exposed wafer may be divided into two or more regions according to error ranges of the overlays. In this way, several regions with large differences in the overlays can be classified into different regions, and compensation values are calculated respectively, thereby improving an effect of the compensation. For example, an overlay threshold is set, positions of the overlays greater than or equal to the overlay threshold are classified into one region, and positions of the overlays less than the overlay threshold are classified into another region. Alternatively, N(N>=2) overlay thresholds are set, and the exposed wafer is divided into N+1 regions according to a threshold interval composed of the overlay thresholds.

It should be noted that a sequence of step S11 and step S12 is not limited. The exposed wafer may be divided into a plurality of regions first, and then overlays of positions in the regions are acquired, which is not limited herein. For example, the exposed wafer may be divided into a plurality of regions according to physical properties and/or process conditions of the regions of the to-be-exposed wafer first, and then overlays of the to-be-exposed wafer are acquired. Specifically, the exposed wafer may be divided into a central region and a peripheral region in advance according to characteristics of CMP or an etching process, then overlays of the central region and the peripheral region are acquired, compensation values corresponding to the regions are calculated respectively according to the overlays, and the central region and the peripheral region of the to-be-exposed wafer are compensated by using the compensation values. With such a compensation method, the characteristics of the CMP or etching process can be compensated. Overlays of the to-be-exposed wafer may also be acquired first, and then the exposed wafer is divided into the plurality of regions according to the overlays of the exposed wafer. In actual production, sometimes when overlays of different regions have significant differences, it may not be immediately known which process leads to the differences or that the differences are caused by a comprehensive effect of multiple processes. In this case, overlay compensation can be performed quickly and effectively by making division directly with values of the overlays.

In S13, compensation values corresponding to the regions are calculated respectively according to the overlays corresponding to the regions.

In one example, overlays in the central region and the edge region of the exposed wafer are acquired, and compensation values in the central region and the edge region are calculated. In this step, as shown in FIG. 2 which is a schematic diagram of overlays of the central region of the exposed wafer and overlays of the edge region, the compensation values of the central region are calculated according to the overlays in the central region, and the compensation values of the edge region are calculated according to the overlays in the edge region. Specifically, the compensation values of the central region are calculated by using overlays measured by the overlays in positions of the central region. The compensation value is a first-order compensation value, the compensation value includes: any one of a rotation compensation value, an expansion compensation value and a translation compensation value and any combination thereof, and the first-order compensation value is updated online. Similarly, the compensation values of the edge region are calculated by using overlays measured by the overlays in positions of the edge region. A calculation process of the first-order compensation value is simple, facilitating rapid calculation and online update of a processing system.

In S14, corresponding regions of a to-be-exposed wafer are compensated respectively by using the compensation values.

In this step, it may be understood that the to-be-exposed wafer is divided in a same division manner as the exposed wafer, and the regions of the exposed wafer are in one-to-one correspondence to the regions of the to-be-exposed wafer. As an example, the exposed wafer is divided into a central region and an edge region, the compensation value corresponding to the central region is W1/2/3 (i.e., the rotation compensation value, the expansion compensation value and the translation compensation value of the central region), and the compensation value corresponding to the edge region is V1/2/3 (i.e., the rotation compensation value, the expansion compensation value and the translation compensation value of the edge region). The to-be-exposed wafer is divided into a central region and an edge region the same as those of the exposed wafer, overlay compensation is performed for the central region of the to-be-exposed wafer by using W1/2/3, and overlay compensation is performed for the edge region of the to-be-exposed wafer by using V1/2/3. Specifically, the compensation values of the overlays include a wafer-level compensation value and a shot-level compensation value.

Optionally, prior to the step of compensating corresponding regions of a to-be-exposed wafer respectively by using the compensation values, the overlay compensation method may further include: judging whether physical properties and/or process conditions of the regions of the to-be-exposed wafer match the overlays; and performing, if yes, the step of compensating corresponding regions of a to-be-exposed wafer respectively by using the compensation values. In this way, a problem of inaccurate compensation for the corresponding regions of the to-be-exposed wafer caused by a data error in the overlays can be avoided, thereby improving the accuracy of the compensation for the wafer. Specifically, the to-be-exposed wafer is divided into a central region and an edge region according to an etching condition of the to-be-exposed wafer, for example, densities and directions of etched ions forming overlay marks of a previous layer at positions at different distances from a center of the to-be-exposed wafer. The central region is a concentric circle of the exposed wafer, and the concentric circle has a diameter of 140 mm. Overlays of the exposed wafer are acquired, an overlay threshold is set, and according to the overlays and the overlay threshold, as shown in FIG. 2, the exposed wafer can be divided into a central region and an edge region. The central region is a concentric circle of the exposed wafer, and the concentric circle has a diameter of 140 mm. In this case, results of the division according to the physical properties and/or the process conditions of the regions of the to-be-exposed wafer are consistent with those of the division according to the overlays of the exposed wafer, and the physical properties and/or the process conditions of the regions of the to-be-exposed wafer may be considered to match the overlays, and the corresponding regions of the to-be-exposed wafer are compensated by using compensation values calculated by the overlays of the regions of the exposed wafer, as shown in FIG. 3 which is a simulation diagram of the compensation values and the overlays according to this embodiment. Curve portions are ideal compensation values, and broken-line portions compensation values calculated according to the overlays of the central region and the peripheral region respectively, and the compensation values calculated respectively are closer to the ideal compensation values.

The physical properties may include any one of a film thickness, film stress, a size of a same pattern in a shot, and a position of the same pattern in the shot and any combination thereof, and the process conditions for the regions of the to-be-exposed wafer may include any one of a CMP condition, an etching condition, a baking condition, a deposition condition, a cleaning condition, an ion implantation condition, and a lithography conditions and any combination thereof. It should be noted that the process conditions for the regions of the to-be-exposed wafer herein refer to process conditions at different positions on a monolithic wafer. For example, the CMP condition may be understood as polishing pressures at different positions in a radial direction of the wafer. In actual process production, the polishing pressures at different positions in the radial direction of the wafer are adjustable. The polishing pressures, when not set to be optimal, may have different effects on the overlay marks at different positions in the radial direction of the wafer, which results in significant differences in the measured overlays during a subsequent lithography process.

Compared with the prior art, according to the embodiments of the present application, overlays of an exposed wafer are acquired, the exposed wafer is divided into a plurality of regions, compensation values corresponding to the regions are calculated respectively according to the overlays corresponding to the regions, and corresponding regions of a to-be-exposed wafer are compensated respectively by using the compensation values; that is, compensation values of different regions of the exposed wafer are obtained by using overlays of the different regions, and the regions of the to-be-exposed wafer are compensated respectively by using the compensation values of the regions, which not only realizes the compensation for the different regions of the wafer, but also can perform continuous update and compensation according to an actual situation, so as to improve the accuracy of the compensation for the wafer, reduce overlays of the wafer and improve a product yield.

Division of the steps of the above methods is only for ease of description, and during implementation, the steps may be combined into one step or some steps may be split into multiple steps, all of which shall fall within the protection scope of the present application provided that a same logical relationship is included. Insignificant modifications added to or insignificant designs introduced in an algorithm or a procedure without changing the core of the algorithm or the procedure shall fall within the protection scope of the patent.

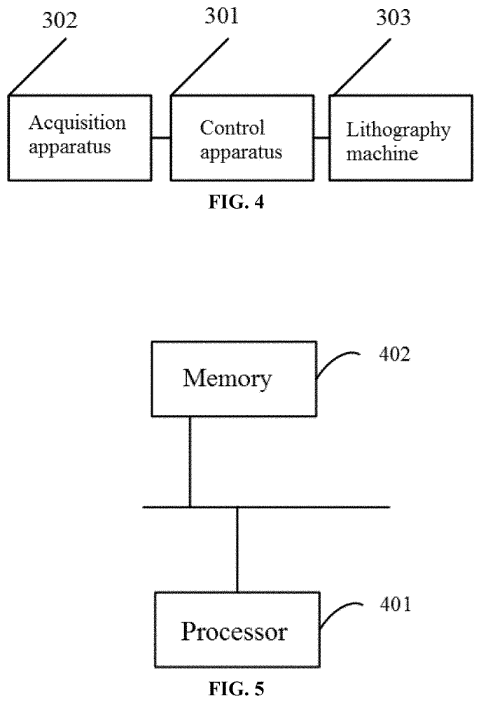

An embodiment of the present application further relates to a wafer exposure system, as shown in FIG. 4, including: a control apparatus 301, and an acquisition apparatus 302 and a lithography machine 303 that are connected to the control apparatus 301. The acquisition apparatus 302 is configured to acquire overlays of an exposed wafer. The control apparatus 301 is configured to divide the exposed wafer into a plurality of regions, and calculate compensation values corresponding to the regions respectively according to the overlays corresponding to the regions. The lithography machine 303 is configured to compensate corresponding regions of a to-be-exposed wafer respectively by using the compensation values.

Specifically, the lithography machine 303 is configured to compensate corresponding positions of the to-be-exposed wafer respectively by using overlays corresponding to all or some of the positions in the exposed wafer and the compensation values corresponding to the regions, and then perform exposure.

It is not difficult to find that this embodiment is a system embodiment corresponding to the above embodiment, and this embodiment can be implemented in coordination with the above embodiment. The relevant technical details mentioned in the above embodiment remain valid in this embodiment and are not repeated here to reduce repetition. Correspondingly, the relevant technical details mentioned in this embodiment can also be applied to the above embodiment.

An embodiment of the present application further relates to a server, as shown in FIG. 5, including: at least one processor 401; and a memory 402 in communication connection with the at least one processor 401. The memory 402 stores instructions executable by the at least one processor 401. The instructions are executed by the at least one processor 401 to enable the at least one processor 401 to perform the overlay compensation method described as above.

The memory 402 and the processor 401 are connected by a bus. The bus may include any number of interconnected buses and bridges. The bus connects various circuits of one or more processors 401 and the memory 402. The bus may also connect various other circuits, such as peripherals, a voltage regulator, and a power management circuit, as is well known in the art, and therefore, are not further described herein. A bus interface provides an interface between the bus and a transceiver. The transceiver may be one or more elements, such as a plurality of receivers and transmitters, that provide a unit for communicating with various other apparatuses on a transmission medium. Data processed by the processor 401 is transmitted over a wireless medium via an antenna. Further, the antenna also receives the data and transmits the data to the processor 401.

The processor 401 is responsible for managing the bus and normal processing, and may also provide various functions including timing, peripheral interfacing, voltage regulation, power management, and other control functions. The memory 402 may be configured to store data used by the processor 401 when performing operations.

An embodiment of the present application further relates to a computer-readable storage medium storing a computer program. The computer program, when executed by the processor, implements the above method embodiment.

Persons of ordinary skill in the art should understand that all or some of the steps of the method in the embodiments may be implemented by a program instructing relevant hardware. The program is stored in a storage medium and includes several instructions to enable a device (which may be a single-chip microcomputer, a chip, or the like) or a processor to perform all or some of the steps of the method in the embodiments of the present application. The foregoing storage medium includes various media that can store program code, such as a USB flash drive, a removable hard disk, a read-only memory (ROM), a random access memory (RAM), a magnetic disk, or an optical disc.

Persons of ordinary skill in the art can understand that, the above embodiments are specific embodiments for implementation of the present application, and during actual application, various changes may be made to the embodiments in form and detail, such as by combining two or more embodiments, without departing from the spirit and scope of the present application.

What is claimed is:

1. An overlay compensation method, comprising:
acquiring overlays of an exposed wafer;
dividing the exposed wafer into a plurality of regions;
calculating compensation values corresponding to the regions respectively according to the overlays corresponding to the regions; and
compensating corresponding regions of a to-be-exposed wafer respectively by using the compensation values.

2. The overlay compensation method according to claim 1, wherein process conditions for forming the exposed wafer and the to-be-exposed wafer are identical.

3. The overlay compensation method according to claim 1, prior to said compensating corresponding regions of a to-be-exposed wafer respectively by using the compensation values, further comprising:
judging whether physical properties and/or process conditions of the regions of the to-be-exposed wafer match the overlays; and
performing, if yes, the step of compensating corresponding regions of a to-be-exposed wafer respectively by using the compensation values.

4. The overlay compensation method according to claim 1, wherein said dividing the exposed wafer into a plurality of regions comprises:
dividing the exposed wafer into a central region and an edge region surrounding the central region or dividing the exposed wafer into two semicircular regions.

5. The overlay compensation method according to claim 1, wherein said dividing the exposed wafer into a plurality of regions comprises:
dividing the exposed wafer into the plurality of regions according to the overlays of the exposed wafer.

6. The overlay compensation method according to claim 5, wherein said dividing the exposed wafer into the plurality of regions according to the overlays of the exposed wafer comprises:
setting an overlay threshold, classifying positions of the overlays greater than or equal to the overlay threshold into one region, and classifying positions of the overlays less than the overlay threshold into another region.

7. The overlay compensation method according to claim 5, wherein said dividing the exposed wafer into the plurality of regions according to the overlays of the exposed wafer comprises:
setting N(N>=2) overlay thresholds, and dividing the exposed wafer into N+1 regions according to a threshold interval composed of the overlay thresholds.

8. The overlay compensation method according to claim 1, wherein the compensation value is a first-order compensation value, and the first-order compensation value is updated online.

9. The overlay compensation method according to claim 8, wherein the compensation value comprises: any one of a rotation compensation value, an expansion compensation value and a translation compensation value and any combination thereof.

10. A wafer exposure system, comprising: a control apparatus, and an acquisition apparatus and a lithography machine that are connected to the control apparatus;
the acquisition apparatus being configured to acquire overlays of an exposed wafer;
the control apparatus being configured to divide the exposed wafer into a plurality of regions, and calculate compensation values corresponding to the regions respectively according to the overlays corresponding to the regions; and
the lithography machine being configured to compensate corresponding regions of a to-be-exposed wafer respectively by using the compensation values.

11. A server implementing the overlay compensation method according to claim 1, comprising:
at least one processor; and
a memory in communication connection with the at least one processor; wherein the memory stores instructions executable by the at least one processor, the instructions being executed by the at least one processor to enable the at least one processor to perform steps of the overlay compensation method.

12. A non-transitory computer-readable storage medium storing a computer program, wherein the computer program, when executed by a processor, implements the overlay compensation method according to claim 1.
